(19) United States
(12) Patent Application Publication
(10) Pub. No.: US 2025/0120228 A1
(43) Pub. Date: Apr. 10, 2025

(54) DISPLAY DEVICE AND MOBILE ELECTRONIC DEVICE INCLUDE THE SAME

(71) Applicant: SAMSUNG DISPLAY CO., LTD., YONGIN-SI (KR)

(72) Inventors: Choon Hyop LEE, Yongin-si (KR); Jung Hak KIM, Yongin-si (KR); Sang Wook YOO, Yongin-si (KR); Jae Uk CHOI, Yongin-si (KR)

(21) Appl. No.: 18/774,393

(22) Filed: Jul. 16, 2024

(30) Foreign Application Priority Data
Oct. 6, 2023 (KR) 10-2023-0133826

(51) Int. Cl. H01L 33/58; G06F 3/044; H01L 33/44; H01L 33/54; H01Q 1/24

(52) U.S. Cl. CPC H10H 20/855; G06F 3/0443; H01Q 1/243; H10H 20/84; H10H 20/853

(57) ABSTRACT

A display device includes a display panel including a display area and a non-display area. The display panel includes a substrate, a display layer disposed on the substrate, an encapsulation layer disposed on the display layer, a sensor electrode layer disposed on the encapsulation layer, and a polarizing layer disposed on the sensor electrode layer. The polarizing layer including a polarizing portion corresponding to the display area and an antenna electrode corresponding to the non-display area.

### CROSS-REFERENCE TO RELATED APPLICATION

This application claims priority under 35 U.S.C. § 119 to Korean Patent Application No. 10-2023-0133826, filed on Oct. 6, 2023 in the Korean Intellectual Property Office, the contents of which are herein incorporated by reference in its entirety.

### TECHNICAL FIELD

The present disclosure relates to displays and, more particularly, to a display device and a mobile electronic device including the same.

### DISCUSSION OF THE RELATED ART

Today, there are various types of display devices with different form factors. Display devices are often used in various electronic devices such as a smart phone, a digital camera, a laptop computer, a navigation system, and a smart television.

A display device designed for inclusion in a mobile electronic device may include an antenna for transmitting and receiving electromagnetic waves. For example, the display device may include an antenna for sending and receiving fourth generation (4G) mobile communication and fifth generation (5G) mobile communication such as long term evolution (LTE). Various frequency bands of the electromagnetic waves may depend on communication technologies, and a shape and a length of the antenna may be varied depending on the frequency bands of the electromagnetic waves that are being sent and received.

### SUMMARY

A display device includes a display panel including a display area and a non-display area. The display panel includes a substrate, a display layer disposed on the substrate, an encapsulation layer disposed on the display layer, a sensor electrode layer disposed on the encapsulation layer, and a polarizing layer disposed on the sensor electrode layer. The polarizing layer includes a polarizing portion corresponding to the display area and an antenna electrode corresponding to the non-display area.

The polarizing layer may include a pressure sensitive adhesive (PSA), a polyvinyl alcohol (PVA) disposed on the PSA, a metal layer disposed on the PVA, the metal layer including the antenna electrode, and tri-acetyl cellulose (TAC) or polyethylene terephthalate (PET) disposed on the metal layer.

The antenna electrode may include a first antenna electrode disposed in a first non-display area positioned at a first side of the display area, and a second antenna electrode disposed in a second non-display area positioned at a second side of the display area. The first side and the second side of the display area may be adjacent to each other.

An elongation axis of the PVA may be arranged in a first direction parallel with a short side of the display panel, and each of the first antenna electrode and the second antenna electrode may have a metal mesh shape.

The elongation axis of the PVA may be arranged in a second direction parallel with a long side of the display panel, and each of the first antenna electrode and the second antenna electrode may have a metal mesh shape.

The elongation axis of the PVA may be arranged in a diagonal direction having an angle designated with respect to a short side of the display panel, and each of the first antenna electrode and the second antenna electrode may have a metal mesh shape.

The metal layer may include a blackening coating layer covering a surface of the antenna electrode.

The blackening coating layer may include a plating film including copper.

The blackening coating layer may include a halogenated silver salt.

The blackening coating layer may include a coating film including aluminum.

The metal layer may include an insulating film covering the blackening coating layer.

The polarizing layer may include a PSA, a PVA disposed on the PSA, TAC disposed on the PSA, and a metal layer disposed on the TAC, the metal layer including the antenna electrode.

The polarizing layer may include a PSA, a PVA disposed on the PSA, PET disposed on the PSA, and a metal layer disposed on the PET, the metal layer including the antenna electrode.

The polarizing layer may include an antenna wiring and an antenna pad, which are electrically connected to the antenna electrode, and the antenna pad may be connected to an antenna FPCB.

The polarizing layer may include a through hole connecting the antenna electrode with the sensor electrode layer. The sensor electrode layer may include an antenna wiring and an antenna pad, which are electrically connected to the through hole. The antenna pad may be connected to a touch FPCB.

A mobile electronic device includes a display panel including a display area and a non-display area. The display panel includes a substrate, a display layer disposed on the substrate, an encapsulation layer disposed on the display layer, a sensor electrode layer disposed on the encapsulation layer, and a polarizing layer disposed on the sensor electrode layer. The polarizing layer includes a polarizing portion corresponding to the display area and an antenna electrode corresponding to the non-display area.

The polarizing layer may include a pressure sensitive adhesive (PSA), a polyvinyl alcohol (PVA) disposed on the PSA, a metal layer disposed on the PVA, the metal layer including the antenna electrode, and tri-acetyl cellulose (TAC) or polyethylene terephthalate (PET) disposed on the metal layer.

The antenna electrode may include a first antenna electrode disposed in a first non-display area at a first side of the display area, and a second antenna electrode disposed in a second non-display area at a second side of the display area. The first side and the second side of the display area may be to be adjacent to each other.

An elongation axis of the PVA may be arranged in a first direction parallel with a short side of the display panel, and each of the first antenna electrode and the second antenna electrode may have a metal mesh shape.

An elongation axis of the PVA may be arranged in a second direction parallel with a long side of the display panel, and each of the first antenna electrode and the second antenna electrode may have a metal mesh shape.

### BRIEF DESCRIPTION OF THE DRAWINGS

The above and other aspects and features of the present disclosure will become more apparent by describing in detail exemplary embodiments thereof with reference to the attached drawings, in which:

FIGS. 1 and 2 are plan views illustrating a display device according to an embodiment of the present disclosure;

FIGS. 3 and 4 are cross-sectional views illustrating a display device according to an embodiment of the present disclosure;

FIGS. 5 and 6 are plan views illustrating a display device according to an embodiment of the present disclosure;

FIG. 7 is a plan view illustrating a polarizing layer according to an embodiment of the present disclosure;

FIG. 8 is a plan view illustrating a shape of an antenna electrode when an elongation axis of PVA provided in a polarizing layer, according to an embodiment of the present disclosure, is in a first direction;

FIG. 9 is a plan view illustrating a shape of an antenna electrode when an elongation axis of PVA provided in a polarizing layer, according to an embodiment of the present disclosure, is in a diagonal direction;

FIG. 10 is a plan view illustrating a shape of an antenna electrode when an elongation axis of PVA provided in a polarizing layer, according to an embodiment of the present disclosure, is in a second direction;

FIG. 11 is a schematic cross-sectional view illustrating a stacked structure of a display panel according to an embodiment of the present disclosure;

FIG. 12 is a schematic cross-sectional view illustrating a stacked structure of a display panel according to an embodiment of the present disclosure;

FIG. 13 is a schematic cross-sectional view illustrating a stacked structure of a polarizing layer, according to an embodiment of the present disclosure, which includes a blackening coating layer;

FIG. 14 is a schematic cross-sectional view illustrating a stacked structure of a polarizing layer, according to an embodiment of the present disclosure, which further includes an insulating film;

FIG. 15 is a schematic cross-sectional view illustrating a stacked structure of a polarizing layer, according to an embodiment of the present disclosure, which includes a blackening coating layer;

FIG. 16 is a schematic cross-sectional view illustrating a stacked structure of a polarizing layer, according to an embodiment of the present disclosure, which further includes an insulating film;

FIG. 17 is a schematic cross-sectional view illustrating a display device to describe connection between an antenna electrode of a polarizing layer and an antenna circuit board; and

FIG. 18 is a schematic cross-sectional view illustrating a display device to describe connection between an antenna electrode of a polarizing layer and an antenna circuit board.

### DETAILED DESCRIPTION OF THE DISCLOSURE

Embodiments of the present invention will now be described more fully hereinafter with reference to the accompanying drawings. This invention may, however, be embodied in different forms and should not necessarily be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers may indicate the same components throughout the specification and the drawings.

It will be understood that, although the terms “first,” “second,” etc. may be used herein to describe various elements, these elements should not necessarily be limited by these terms. These terms are used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, specific embodiments will be described with reference to the accompanying drawings.

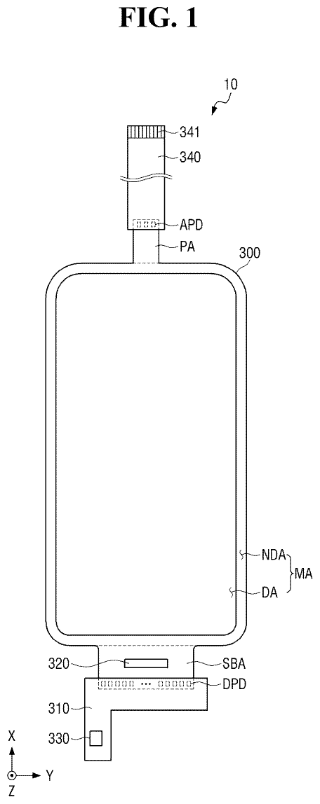

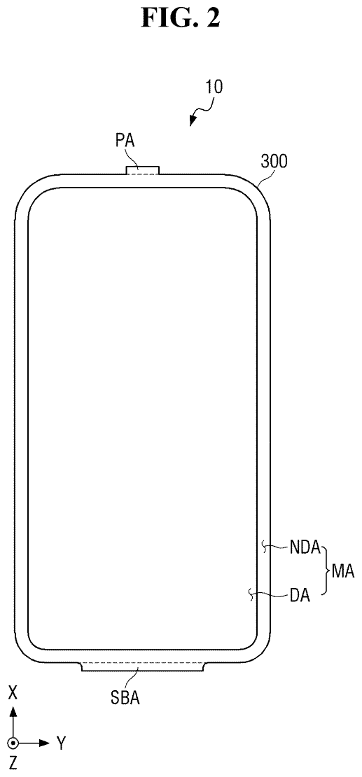

FIGS. 1 and 2 are plan views illustrating a display device according to an embodiment of the present disclosure.

Referring to FIGS. 1 and 2, a display device 10, according to an embodiment of the present disclosure, may be applied to a mobile electronic device such as a mobile phone, a smart phone, a tablet computer, a mobile communication terminal, an electronic diary, an electronic book, a portable multimedia player (PMP), a navigation system, and an ultra mobile PC (UMPC). Otherwise, the display device 10, according to an embodiment of the present disclosure, may be applied to a television, a laptop computer, a computer monitor, a digital signboard or a display unit of Internet of things (IoT) device. Otherwise, the display device 10, according to an embodiment of the present disclosure may be applied to a wearable device such as a smart watch, a watch phone, an eyeglasses-type display and a head mounted display (HMD). Otherwise, the display device 10, according to an embodiment of the present disclosure, may be applied to a center information display (CID) disposed in a dashboard of a vehicle, a room mirror display that replaces a side mirror of a vehicle or a display disposed on a rear surface of a front seat as an entertainment for a rear seat of a vehicle.

In the present disclosure, a first direction (e.g., X-axis direction) is a short side direction of the display device 10, and may be, for example, a vertical direction of the display device 10. A second direction (e.g., Y-axis direction) is a long side direction of the display device 10, and may be, for example, a horizontal direction of the display device 10. A third direction (e.g., Z-axis direction) may be a thickness direction of the display device 10. A corner where the long side in the first direction (e.g., X-axis direction) and the short side in the second direction (e.g., Y-axis direction) meet may be rounded to have a predetermined curvature or formed at a right angle.

The display device 10, according to an embodiment of the present disclosure, includes a display panel 300, a display circuit board 310, a display driving circuit 320, a touch driving circuit 330 and an antenna circuit board 340. A connector 341 may be formed on one side of the antenna circuit board 340.

The display panel 300 may be a light emitting display panel including a light emitting element. For example, the display panel 300 may be an organic light emitting diode (OLED) display panel using an organic light emitting diode (OLED) including an organic light emitting layer, a micro light emitting diode display panel using a micro LED, a quantum dot light emitting display panel using a quantum dot light emitting diode including a quantum dot light emitting layer or an inorganic light emitting display panel using an inorganic light emitting element including an inorganic semiconductor.

The display panel 300 may be a flexible display panel that is flexible and thus may be easily bent, folded or rolled to a noticeable extent without cracking or otherwise sustaining damage. For example, the display panel 300 may be a foldable display panel that may be folded and unfolded, a curved display panel of which a display surface is curved, a bended display panel in which an area other than the display surface is bent, a rollable display panel that may be rolled or unrolled, or a stretchable display panel that may be elongated.

The display panel 300 may include a main area MA, a sub-area SBA protruded from one side of the main area MA and a protruded area PA protruded from the other side of the main area MA.

The main area MA may include a display area DA for displaying an image and a non-display area NDA that is a peripheral area of the display area DA. The display area DA may occupy most of the main area MA. The display area DA may be disposed at the center of the main area MA. The non-display area NDA may be an outer area of the display area DA. The non-display area NDA may be defined as an edge area of the display panel 300. The non-display area NDA may be referred to as a dead space area DS.

The sub-area SBA may protrude from one side of the main area MA in the first direction (e.g., X-axis direction). For example, one side of the main area MA may be a lower side of the main area MA. As shown in FIG. 1, a length of the sub-area SBA in the first direction (e.g., X-axis direction) may be shorter than that of the main area MA in the first direction (e.g., X-axis direction), and the length of the sub-area SBA in the second direction (e.g., Y-axis direction) may be shorter than that of the main area MA in the second direction (e.g., Y-axis direction), but the embodiment of the present disclosure is not necessarily limited thereto.

Referring to FIG. 2, the sub-area SBA may be bent, and at least a portion of the bent sub-area SBA may be disposed below the display panel 300. In this case, at least a portion of the sub-area SBA may overlap the main area MA of the display panel 300 in the third direction (e.g., Z-axis direction).

Display pads DPD may be disposed at one edge of the sub-area SBA. One edge of the sub-area SBA may be a lower edge of the sub-area SBA. The display circuit board 310 may be attached on the display pads DPD of the sub-area SBA. The display circuit board 310 may be attached to the display pads DPD of the sub-area SBA by using a conductive adhesive such as an anisotropic conductive film and an anisotropic conductive paste. The display circuit board 310 may be a flexible printed circuit board (FPCB) that may be bent, a rigid printed circuit board (PCB) that is rigid and not easily bent, or a composite printed circuit board that includes both a rigid printed circuit board and a flexible printed circuit board.

The display driving circuit 320 may be disposed on the sub-area SBA of the display panel 300. The display driving circuit 320 may receive control signals and power voltages and generate and output signals and voltages for driving the display panel 300. The display driving circuit 320 may be formed of an integrated circuit (IC).

The touch driving circuit 330 may be disposed on the display circuit board 310. The touch driving circuit 330 may be formed of an integrated circuit. The touch driving circuit 330 may be attached to the display circuit board 310.

The touch driving circuit 330 may be electrically connected to sensor electrodes of the sensor electrode layer of the display panel 300 through the display circuit board 310. The touch driving circuit 330 may output a touch driving signal to each of the sensor electrodes and detect a voltage change according to mutual capacitance of the sensor electrodes.

The sensor electrode layer of the display panel 300 may sense a proximity touch and/or a contact touch. The contact touch may be a direct contact to a cover window of the display panel 300 by an object, such as a person's finger or a pen/stylus. The proximity touch may be when an object, such as a person's finger or pen/stylus, is positioned over the cover widow and is spaced apart from the cover window by a small extent, e.g., hovering.

Display pixels of the display panel 300 and a power supply unit for supplying driving voltages for driving the display driving circuit 320 may be additionally disposed on the display circuit board 310. Alternatively, the power supply unit may be integrated with the display driving circuit 320, and in this case, the display driving circuit 320 and the power supply unit may be formed as one integrated circuit.

The protruded area PA may be an area that includes at least one element of a power supply line, a ground line or an antenna electrode of an antenna module for wireless communication. The protruded area PA may be protruded from the other side of the main area MA in the first direction (e.g., X-axis direction). For example, the other side of the main area MA may be an upper side of the main area MA. As shown in FIG. 1, a length of the protruded area PA in the first direction (e.g., X-axis direction) may be shorter than that of the main area MA in the first direction (e.g., X-axis direction), and a length of the protruded area PA in the second direction (e.g., Y-axis direction) may be shorter than that of the main area MA in the second direction (e.g., Y-axis direction), but the embodiment of the present disclosure is not necessarily limited thereto.

As shown in FIG. 2, at least a portion of the protruded area PA may be bent, and at least a portion of the bent protruded area PA may be disposed below the display panel 300. In this case, at least a portion of the protruded area PA may overlap the main area MA of the display panel 300 in the third direction (e.g., Z-axis direction).

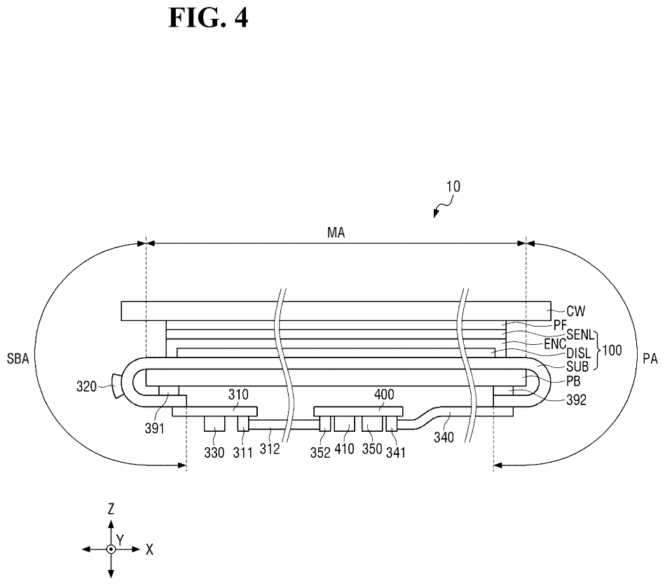

Antenna pads APD may be disposed at one edge of the protruded area PA. The antenna circuit board 340 may be attached onto the antenna pads APD of the protruded area PA. The antenna circuit board 340 may be attached onto the antenna pads APD of the protruded area PA by using a conductive adhesive such as an anisotropic conductive film and an anisotropic conductive adhesive. One side of the antenna circuit board 340 may include a connector 341 connected to a main circuit board 400 on which an antenna driving circuit (350 of FIG. 4) is packaged. The antenna circuit board 340 may be a flexible printed circuit board (FPCB).

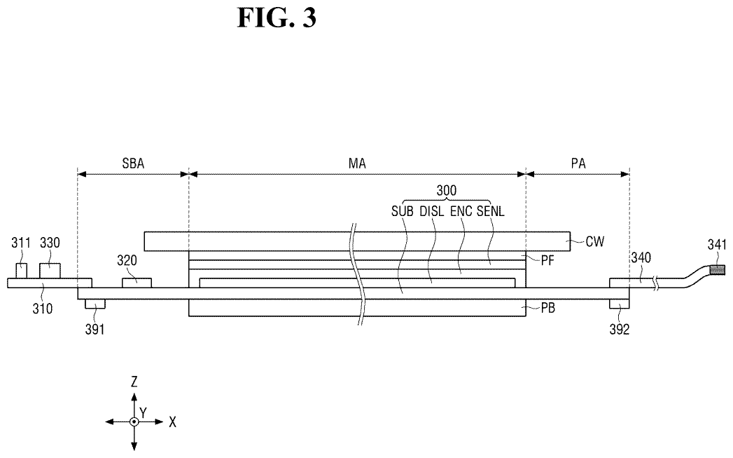

FIGS. 3 and 4 are cross-sectional views illustrating a display device according to an embodiment of the present disclosure.

Referring to FIGS. 3 and 4, the display device 10, according to an embodiment of the present disclosure, may include a display panel 300, a polarizing layer PF, a cover window CW and a panel lower cover PB. The display panel 300 may include a substrate SUB, a display layer DISL, an encapsulation layer ENC and a sensor electrode layer SENL.

The substrate SUB may be made of an insulating material such as a polymer resin. The substrate SUB may be a flexible substrate capable of bending, folding, rolling or the like.

In the main area MA, the display layer DISL may be disposed on the substrate SUB. The display layer DISL may be a layer that includes light emission areas to display an image. The display layer DISL may include a thin film transistor layer on which thin film transistors are formed, and a light emitting element layer in which light emitting elements for emitting light are disposed in the light emission areas.

Scan lines, data lines, power lines, etc. for driving the light emitting elements of the light emission area may be disposed in the display area DA of the display layer DISL. A scan driver for outputting scan signals to the scan lines and fan-out lines connecting the data lines with the display driving circuit 320 may be disposed in the non-display area NDA of the display layer DISL.

The encapsulation layer ENC may be disposed on the display layer DISL. The encapsulation layer ENC may be a layer for encapsulating the light emitting element layer of the display layer DISL to prevent oxygen or moisture from permeating into the light emitting element layer of the display layer DISL. The encapsulation layer ENC may be disposed on an upper surface and sides of the display layer DISL.

The sensor electrode layer SENL may be disposed on the display layer DISL. The sensor electrode layer SENL may include sensor electrodes. The sensor electrode layer SENL may sense a touch by using the sensor electrodes.

The polarizing layer PF may be disposed on the sensor electrode layer SENL. The polarizing layer PF may include a first base, a linear polarizing plate, a phase delay film such as a λ/4 plate (quarter-wave plate), and a second base. The first base, the phase delay film, the linear polarizing plate, and the second base may be sequentially stacked on the sensor electrode layer SENL.

The cover window CW may be disposed on the polarizing layer (e.g., polarizing film) PF. The cover window CW may be attached onto the polarizing layer PF by a transparent adhesive such as an optically clear adhesive (OCA).

The panel lower cover PB may be disposed below the display panel 300. The panel lower cover PB may be attached to a lower surface of the display panel 300 through an adhesive. The adhesive may be a pressure sensitive adhesive (PSA). The panel lower cover PB may include a light blocker for absorbing ambient light, a buffer for absorbing an impact from the outside, and/or a heat dissipator for efficiently discharging heat of the display panel 300.

The light blocker may be disposed below the display panel 300. The light blocker prevents transmission of light to prevent components disposed below the light blocker, for example, the display circuit board 310, etc. from being viewed from an upper portion of the display panel 300. The light blocker may include a light absorbing material such as a black pigment or a black dye.

The buffer may be disposed below the light blocker. The buffer absorbs an external impact to prevent the display panel 300 from being damaged. The buffer may include a single layer or a plurality of layers. For example, the buffer may include a polymer resin such as polyurethane, polycarbonate, polypropylene and polyethylene, or may include a material having elasticity such as a sponge formed by foaming a rubber, a urethane-based material or an acrylic-based material.

The heat dissipator may be disposed below the buffer. The heat dissipator may include a first heat dissipation layer including graphite or carbon nanotubes and a second heat dissipation layer formed of a metal thin film such as copper, nickel, ferrite or silver, which may shield electromagnetic waves and may have excellent thermal conductivity.

According to an embodiment of the present disclosure, as shown in FIG. 4, the substrate SUB may be bent in the sub-area SBA, and may be disposed below the display panel 300. The sub-area SBA of the substrate SUB may be attached to a lower surface of the panel lower cover PB by a first adhesive 391. The first adhesive 391 may be a pressure sensitive adhesive.

According to an embodiment of the present disclosure, as shown in FIG. 4, the protruded area PA of the substrate SUB may be bent, and may be disposed below the display panel 300. The protruded area PA of the substrate SUB may be attached to the lower surface of the panel lower cover PB by a second adhesive 392. The second adhesive 392 may be a pressure sensitive adhesive.

The display circuit board 310 may be attached to the display pads DPD of the sub-area SBA of the substrate SUB by using a conductive adhesive such as an anisotropic conductive film and an anisotropic conductive adhesive. The display circuit board 310 may include a connector 311 connected to the flexible circuit board 312. The display circuit board 310 may be connected to a connector 352 of the main circuit board 400 by the flexible circuit board 312.

The touch driving circuit 330 may be disposed on the display circuit board 310. The touch driving circuit 330 may generate touch data in accordance with a change in an electrical signal sensed in each of the sensor electrodes of the sensor electrode layer of the display panel 300 and transmit the touch data to the main processor 410 of the main circuit board 400, and the main processor 410 may calculate touch coordinates in which the touch has occurred, by analyzing the touch data.

The antenna circuit board 340 may be attached to the antenna pads APD of the protruded area PA of the substrate SUB by using a conductive adhesive such as an anisotropic conductive film and an anisotropic conductive adhesive. The connector 351 of the antenna circuit board 340 may be connected to the connector 351 of the main circuit board 400. The protruded area PA may be connected to the main circuit board 400 by the antenna circuit board 340.

The main circuit board 400 may be a rigid printed circuit board (PCB) that is rigid and not easily bent. The main processor 410 and the antenna driving circuit 350 may be disposed on the main circuit board 400.

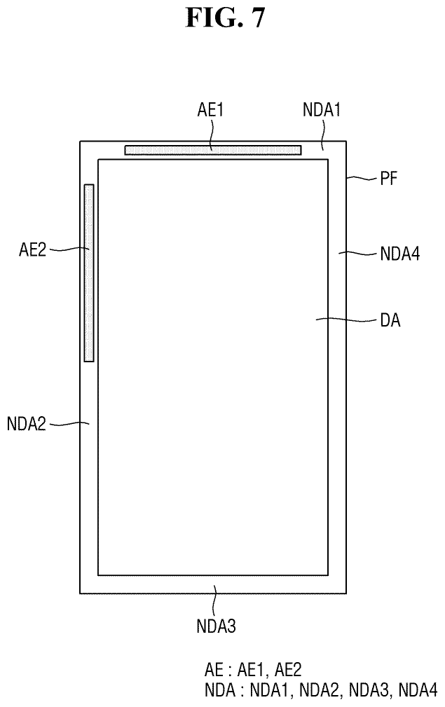

The antenna driving circuit 350 may be electrically connected to antenna electrodes (e.g., AE1 and AE2 of FIG. 7) of the display panel 300 through the antenna circuit board 340. Therefore, the antenna driving circuit 350 may receive an electromagnetic wave signal by the antenna electrodes (e.g., AE1 and AE2 of FIG. 7) and output the electromagnetic wave signal, which is to be transmitted, to the antenna electrodes (e.g., AE1 and AE2 of FIG. 7). The antenna circuit board 340 may include an integrated circuit (IC).

The antenna driving circuit 350 may process electromagnetic wave signals transmitted and received through the antenna electrodes (e.g., AE1 and AE2 of FIG. 7). For example, the antenna driving circuit 350 may change the amplitude of the electromagnetic wave signal received by the antenna electrodes (e.g., AE1 and AE2 of FIG. 7). Alternatively, the antenna driving circuit 350 might not only change the amplitude of the electromagnetic wave signal received by the antenna electrodes, but also change the phase. The antenna driving circuit 350 may transmit the processed electromagnetic wave signal to a mobile communication module. The mobile communication module may be disposed on the main circuit board 400.

The antenna driving circuit 350 may change the amplitude of the electromagnetic wave signal transmitted from the mobile communication module. Alternatively, the antenna driving circuit 350 might not only change the amplitude of the electromagnetic wave signal transmitted from the mobile communication module, but also change the phase. The antenna driving circuit 350 may transmit the processed electromagnetic wave signal to the antenna electrodes (e.g., AE1 and AE2 of FIG. 7).

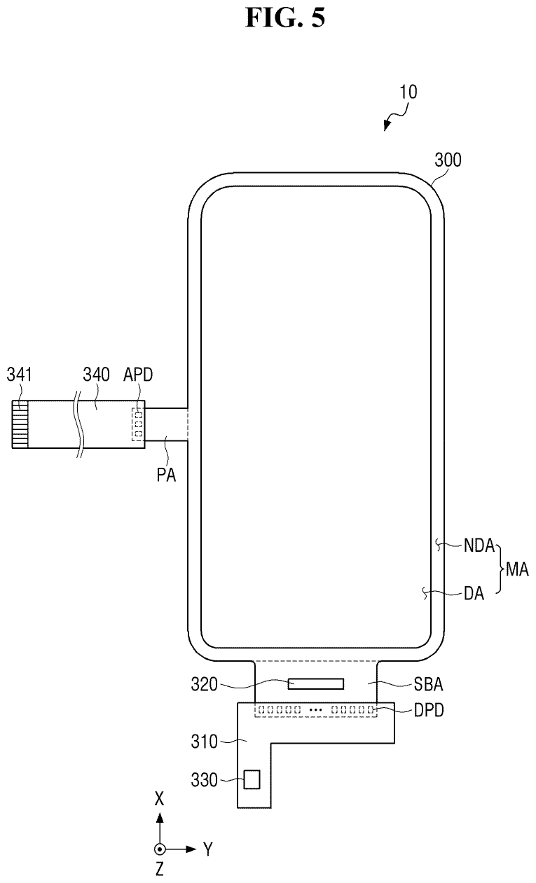

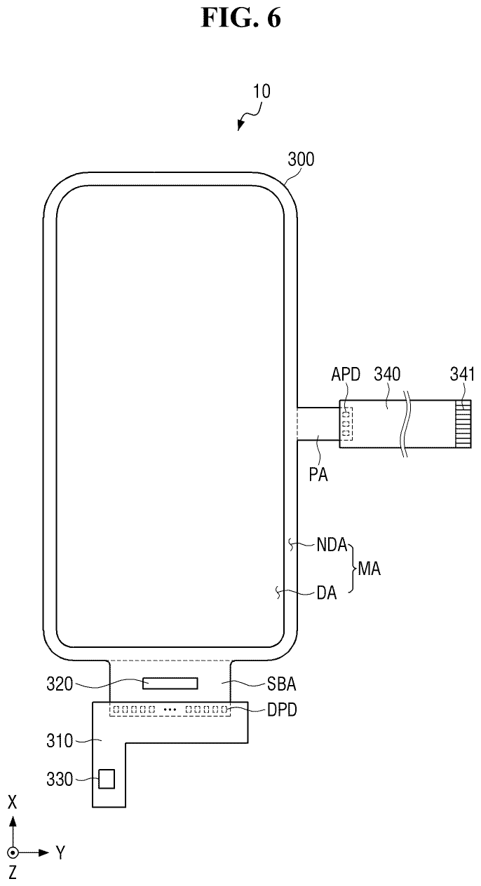

FIG. 5 is a plan view illustrating a display device according to an embodiment of the present disclosure. FIG. 6 is a plan view illustrating a display device according to an embodiment of the present disclosure.

The embodiment of FIG. 5 is different from the embodiment of FIGS. 1 and 2 in that the protruded area PA is protruded from a left side of the main area MA in the second direction (e.g., Y-axis direction). The embodiment of FIG. 6 is different from the embodiment of FIGS. 1 and 2 in that the protruded area PA is protruded from a right side of the main area MA in the second direction (e.g., Y-axis direction). To the extent that an element is not described in detail with respect to FIGS. 5 and 6, it may be understood that the element is at least similar to a corresponding element that has been described elsewhere within the present disclosure.

As shown in FIGS. 5 and 6, the protruded area PA may be protruded from one side of the main area MA, and one side of the main area MA may be any one of an upper side, a lower side, a left side and a right side of the main area MA.

The protruded area PA may be protruded from the lower side of the main area MA in the second direction (e.g., Y-axis direction), and may be spaced apart from the sub-area SBA in the second direction (e.g., Y-axis direction). In this case, the length of the protruded area PA in the first direction (e.g., X-axis direction) may be shorter than that of the sub-area SBA in the first direction (e.g., X-axis direction), and the length of the protruded area PA in the second direction (e.g., Y-axis direction) may be shorter than that of the sub-area SBA in the second direction (e.g., Y-axis direction), but the embodiment of the present disclosure is not necessarily limited thereto.

FIG. 7 is a plan view illustrating a polarizing layer PF according to an embodiment of the present disclosure. For example, FIG. 7 may be a layout view of the polarizing layer PF described with reference to FIG. 4.

Referring to FIG. 7, the polarizing layer PF may include a polarizing portion corresponding to the display area DA and an antenna electrode AE corresponding to the non-display area NDA. The polarization portion may include a linear polarizing plate and/or a phase delay film such as a λ/4 plate (quarter-wave plate). The antenna electrode AE is embedded in the polarizing layer PF and may correspond to the non-display area NDA of the display panel 300.

The antenna electrode AE may include a first antenna electrode AE1 disposed in a first non-display area NDA1 positioned at one side of the display area DA and a second antenna electrode AE2 disposed in a second non-display area NDA2 disposed at the other side of the display area DA. In this case, the one side and the other side of the display area DA may be adjacent to each other.

The non-display area NDA of the display panel 300 may surround the display area DA, and may be divided into a first non-display area NDA1, a second non-display area NDA2, a third non-display area NDA3 and a fourth non-display area NDA4. The first non-display area NDA1 and the third non-display area NDA3 may be disposed on the short side of the display panel 300, and may be opposite to each other with the display area DA interposed therebetween. The second non-display area NDA2 and the fourth non-display area NDA4 may be positioned on the long side of the display panel 300, and may be opposite to each other with the display area DA interposed therebetween.

According to one embodiment, the polarizing layer PF may include an antenna electrode AE in each of the first non-display area NDA1 and the second non-display area NDA2. However, embodiments of the present disclosure are not necessarily limited to the antenna electrode AE of the polarizing layer PF being positioned in the first non-display area NDA1 and the second non-display area NDA2. For example, the antenna electrode AE embedded in the polarizing layer PF may be disposed in the first non-display area NDA1, the second non-display area NDA2, the third non-display area NDA3, and/or the fourth non-display area NDA4.

According to an embodiment of the present disclosure, a driving frequency of the first antenna electrode AE1 and a driving frequency of the second antenna electrode AE2 may be different from each other. Alternatively, the driving frequency of the first antenna electrode AE1 and the driving frequency of the second antenna electrode AE2 may be the same as each other.

According to an embodiment of the present disclosure, the first antenna electrode AE1 and the second antenna electrode AE2 may have a metal mesh shape.

The display device 10, according to an embodiment of the present disclosure, may prevent a visibility problem in which the antenna electrode AE is visible to a user as the antenna electrode AE is embedded in the polarizing layer PF and disposed in the non-display area NDA.

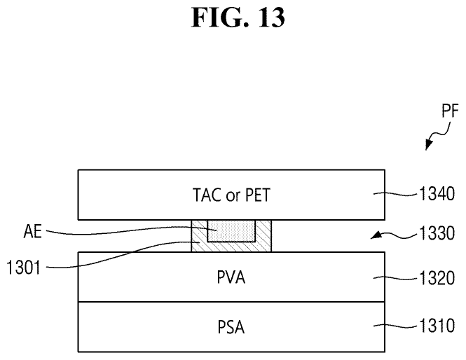

According to an embodiment of the present disclosure, the shape of the antenna electrode AE embedded in the polarizing layer PF may be designed based on a polarization direction according to elongation of the polarizing portion of the polarizing layer PF, for example, polyvinyl alcohol (PVA) (1320 of FIG. 13). For example, the polarization direction of the antenna electrode AE may correspond to a direction of an elongation axis of the PVA 1320 of the polarizing layer PF.

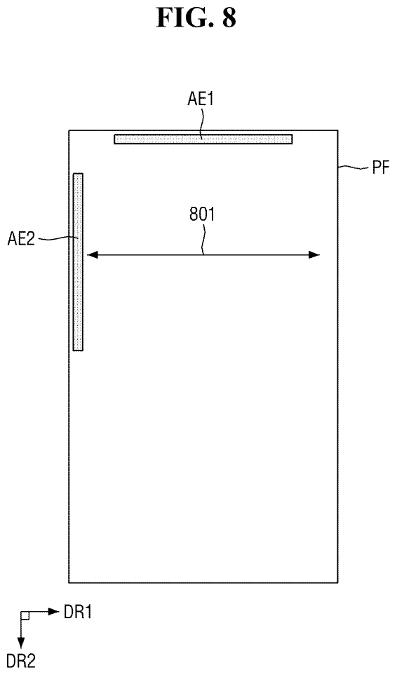

Hereinafter, a patterning shape of the antenna electrode AE according to the direction of the elongation axis of the PVA 1320 of the polarizing layer PF will be described with reference to FIGS. 8 to 10.

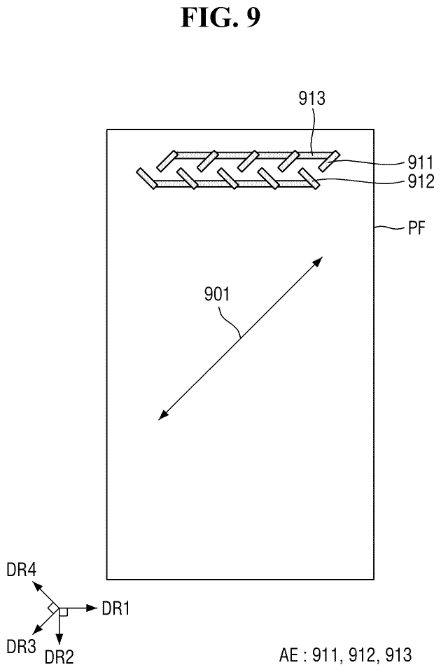

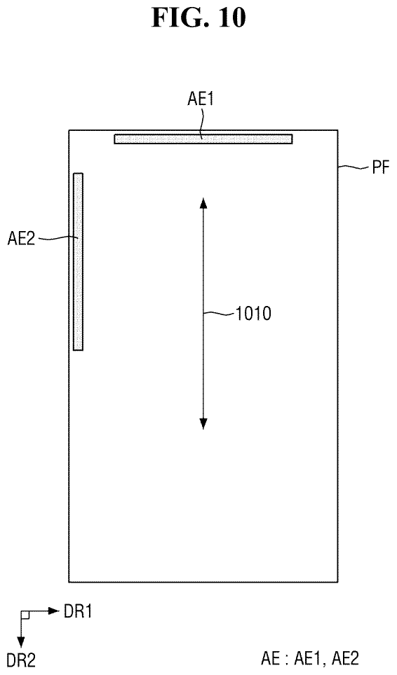

FIG. 8 is a plan view illustrating a shape of an antenna electrode AE when an elongation axis 801 of a PVA 1320 provided in a polarizing layer PF is in a first direction DR1 in accordance with an embodiment of the present disclosure. FIG. 9 is a plan view illustrating a shape of an antenna electrode AE when an elongation axis 901 of a PVA 1320 provided in a polarizing layer PF is in a diagonal direction in accordance with an embodiment of the present disclosure. FIG. 10 is a plan view illustrating a shape of an antenna electrode AE when an elongation axis 1010 of a PVA 1320 provided in a polarizing layer PF is in a second direction DR2 in accordance with an embodiment of the present disclosure.

Referring to FIG. 8, the PVA 1320 of the polarizing layer PF, according to an embodiment of the present disclosure, may be arranged in the first direction DR1 in which a direction of the elongation axis 801 is parallel with the short side of the display panel 300. In this case, each of the first antenna electrode AE1 and the second antenna electrode AE2 may have a metal mesh shape patterned in the first direction DR1. Each of the first antenna electrode AE1 and the second antenna electrode AE2 may have a metal mesh shape patterned in the first direction DR1 to induce polarization of radio waves in the first direction DR1.

Referring to FIG. 9, the PVA 1320 of the polarizing layer PF, according to an embodiment of the present disclosure, may be arranged in a diagonal direction in which a direction of the elongation axis 901 has an angle designated with respect to the short side of the display panel 300. In this case, each of the first antenna electrode AE1 and the second antenna electrode AE2 may have a metal mesh shape patterned in the diagonal direction. Each of the first antenna electrode AE1 and the second antenna electrode AE2 may have a metal mesh shape patterned in the diagonal direction to induce polarization of radio waves in the diagonal direction.

FIG. 9 shows the first antenna electrode AE1 and the second antenna electrode AE2 in greater detail. As shown in FIG. 9, the antenna electrode AE disposed in a specific non-display area NDA includes X-electrodes 911 for X-axis polarization and Y-electrodes 912 for Y-axis polarization. The X-electrodes 911 may be connected to each other by a connection electrode 913. Likewise, the Y-electrodes 912 may be connected to each other by the connection electrode 913. The X-electrodes 911 and the Y-electrodes 912 may be perpendicular to or parallel with the direction of the elongation axis 901 of the PVA 1320. For example, as shown, the X-electrodes 911 may be arranged in parallel with the direction of the elongation axis 901 of the PVA 1320, and the Y-electrodes 912 may be arranged to be perpendicular to the direction of the elongation axis 901 of the PVA 1320.

The features of the X-electrodes 911 for the X-axis polarization and the Y-electrodes 912 for the Y-axis polarization, which are described in FIG. 9, may be equally applied to the embodiments of FIGS. 8 and 10.

Referring to FIG. 10, the PVA 1320 of the polarizing layer PF, according to an embodiment of the present disclosure, may be arranged in the second direction DR2 in which a direction of an elongation axis 1010 is parallel with the long side of the display panel 300. In this case, each of the first antenna electrode AE1 and the second antenna electrode AE2 may have a metal mesh shape patterned in the second direction DR2. Each of the first antenna electrode AE1 and the second antenna electrode AE2 may have a metal mesh shape patterned in the second direction DR2 to induce polarization of radio waves in the second direction DR2.

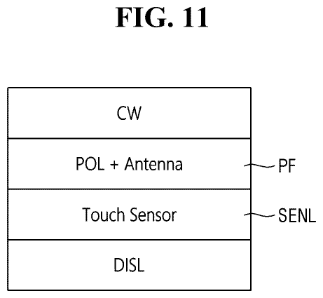

FIG. 11 is a schematic cross-sectional view illustrating a stacked structure of a display panel 300 according to an embodiment of the present disclosure. For example, the display panel 300 shown in FIG. 11 may be substantially the same as or similar to the display panel 300 described with reference to FIGS. 1 to 10.

Referring to FIG. 11, the display panel 300, according to an embodiment of the present disclosure, may include a display layer DISL disposed on a substrate, a sensor electrode layer SENL disposed on the display layer DISL, a polarizing layer PF disposed on the sensor electrode layer SENL, including an antenna electrode AE, and a cover window CW disposed on the polarizing layer PF.

As described with reference to FIGS. 7 to 10, the polarizing layer PF may include an antenna electrode AE. In the display panel 300, according to an embodiment of the present disclosure, the polarizing layer PF in which the antenna electrode AE is positioned and the display layer DISL are spaced apart from each other, whereby antenna efficiency may be enhanced. For example, in comparison with a comparative example in which the antenna electrode AE is embedded in the sensor electrode layer SENL, an embodiment of the present disclosure may reduce interference between the antenna electrode AE and electrodes (e.g., cathode electrode) provided in the display layer DISL.

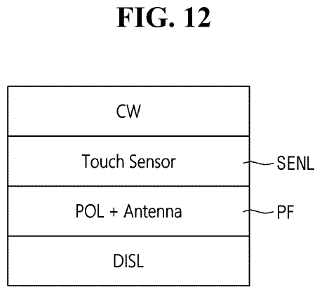

FIG. 12 is a schematic cross-sectional view illustrating a stacked structure of a display panel 300 according to an embodiment of the present disclosure.

The embodiment of FIG. 12 is different from the embodiment of FIG. 11 in that the polarizing layer PF is disposed between the sensor electrode layer SENL and the display layer DISL. Although it has been described in FIG. 11 that the polarizing layer PF including the antenna electrode AE is disposed on the sensor electrode layer SENL, the embodiment of the present disclosure is not necessarily limited thereto. For example, as shown in FIG. 12, the polarizing layer PF including the antenna electrode AE may be disposed between the sensor electrode layer SENL and the display layer DISL.

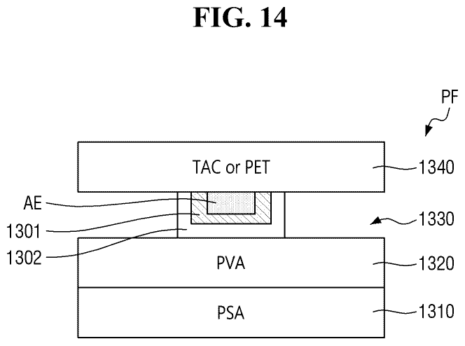

FIG. 13 is a schematic cross-sectional view illustrating a stacked structure of a polarizing layer PF according to an embodiment of the present disclosure, which includes a blackening coating layer 1301. FIG. 14 is a schematic cross-sectional view illustrating a stacked structure of a polarizing layer PF, according to an embodiment of the present disclosure, which further includes an insulating film.

Referring to FIGS. 13 and 14, the polarizing layer PF, according to an embodiment of the present disclosure, may include a pressure sensitive adhesive (PSA) 1310 that is an adhesive layer, a PVA 1320 that is disposed on the PSA 1310 and is a polarizing resin film, a metal layer 1330 that is disposed on the PVA 1320 and includes an antenna electrode AE, and tri-acetyl cellulose (TAC) or polyethylene terephthalate (PET) 1340 disposed on the metal layer 1330.

According to an embodiment of the present disclosure, the metal layer 1330 of the polarizing layer PF may include a blackening coating layer covering a surface of the antenna electrode AE. The blackening coating layer 1301 serves to reduce visibility of the antenna electrode AE by reducing reflectivity of the antenna electrode AE.

The blackening coating layer 1301 may include a plating film that includes copper. The plating film may cover a surface of a metal that forms the antenna electrode AE.

The blackening coating layer 1301 may include a coating film of a halogenated silver salt. The coating film may cover the surface of the metal that forms the antenna electrode AE.

The blackening coating layer 1301 may include a coating film that includes aluminum. The coating film may cover the surface of the metal that forms the antenna electrode AE.

An uneven surface processing may be applied to the surface of the metal that forms the antenna electrode AE. As the surface of the antenna electrode AE is processed in an uneven shape, reflectivity may be reduced and visibility of the antenna electrode AE may be reduced.

According to an embodiment of the present disclosure, as shown in FIG. 14, the metal layer 1330 of the polarizing layer PF may further include an insulating film 1302 covering the blackening coating layer 1301. The insulating film 1302 serves to prevent interference between a propagation signal transmitted and received through the antenna electrode AE and the display layer DISL.

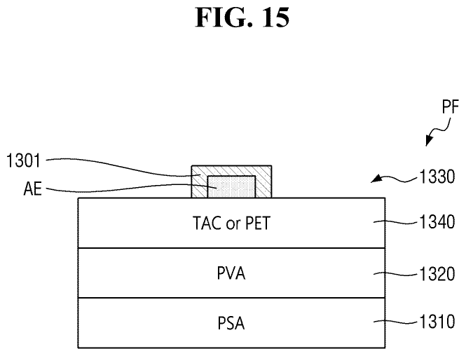

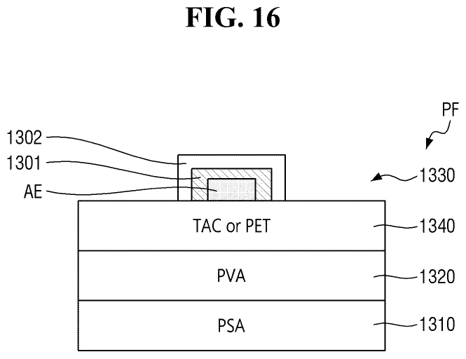

FIG. 15 is a schematic cross-sectional view illustrating a stacked structure of a polarizing layer PF according to an embodiment of the present disclosure, which includes a blackening coating layer 1301. FIG. 16 is a schematic cross-sectional view illustrating a stacked structure of a polarizing layer PF according to an embodiment of the present disclosure, which further includes an insulating film.

The embodiment of FIGS. 15 and 16 is different from the embodiment of FIGS. 13 and 14 in that the metal layer 1330 is disposed on the uppermost layer of the polarizing layer PF.

Referring to FIG. 15 and FIG. 16, the polarizing layer PF, according to an embodiment of the present disclosure, may include a pressure sensitive adhesive (PSA) 1310 that is an adhesive layer, a PVA 1320 that is disposed on the PSA 1310 and is a polarizing resin film, tri-acetyl cellulose (TAC) or polyethylene terephthalate (PET) 1340 disposed on the PVA 1320, and a metal layer 1330 that is disposed on the tri-acetyl cellulose (TAC) or polyethylene terephthalate (PET) 1340 and includes the antenna electrode AE.

In the same manner as the embodiment of FIGS. 13 and 14, the metal layer 1330, according to the embodiment of FIGS. 15 and 16, may include a blackening coating layer 1301 covering the surface of the antenna electrode AE. In addition, an insulating film 1302 covering the blackening coating layer 1301 may be further provided.

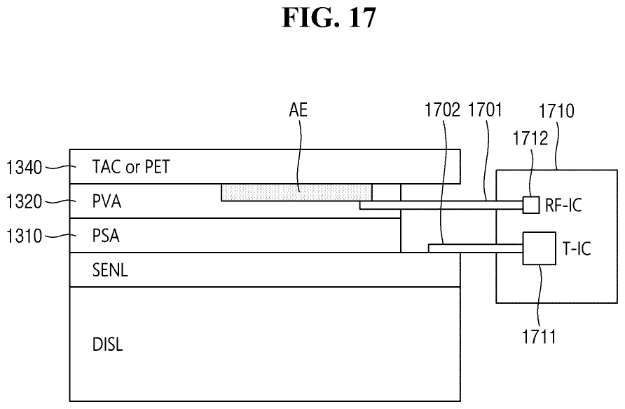

FIG. 17 is a schematic cross-sectional view illustrating a display device 10 to describe connection between an antenna electrode AE of a polarizing layer PF and an antenna circuit board 340. For example, the polarizing layer PF shown in FIG. 17 may be substantially the same as or similar to the polarizing layer PF described with reference to FIGS. 1 to 10.

Referring to FIG. 17, a display panel 300 of an electronic device, according to an embodiment of the present disclosure, may include a substrate (SUB of FIG. 4), a display layer DISL disposed on the substrate SUB, an encapsulation layer (ENC of FIG. 4) disposed on the display layer DISL, a sensor electrode layer SENL disposed on the encapsulation layer ENC, and a polarizing layer PF disposed on the sensor electrode layer SENL.

The polarizing layer PF is a component disposed on the sensor electrode layer SENL, and may include a pressure sensitive adhesive (PSA) 1310 that is an adhesive layer, a PVA 1320 that is disposed on the PSA 1310 and is a polarizing resin film, a metal layer 1330 that is disposed on the PVA 1320 and includes the antenna electrode AE, and tri-acetyl cellulose (TAC) or polyethylene terephthalate (PET) 1340 disposed on the metal layer 1330.

According to an embodiment of the present disclosure, the polarizing layer PF may include an antenna wiring and an antenna pad (APD of FIG. 2), which are electrically connected to the antenna electrode AE. The antenna pad APD may be disposed on one side of the polarizing layer PF positioned in the non-display area NDA. An antenna FPCB 1701 may be attached to the antenna pad APD, and the antenna pad APD may be electrically connected to a circuit board 1710 in which an antenna driving circuit (e.g., RF IC) 1712 is disposed through the antenna FPCB 1701. The circuit board 1710 may be the main circuit board 400 or the antenna circuit board 340 described with reference to FIGS. 1 to 5.

A touch driving circuit (e.g., touch IC) 1711, as well as the antenna driving circuit (e.g., RF IC) 1712, may be disposed in the circuit board 1710. In this case, the touch driving circuit (e.g., touch IC) 1711 may be electrically connected to touch electrodes of the sensor electrode layer SENL through a touch FPCB 1702 attached to one side of the sensor electrode layer SENL corresponding to the non-display area NDA.

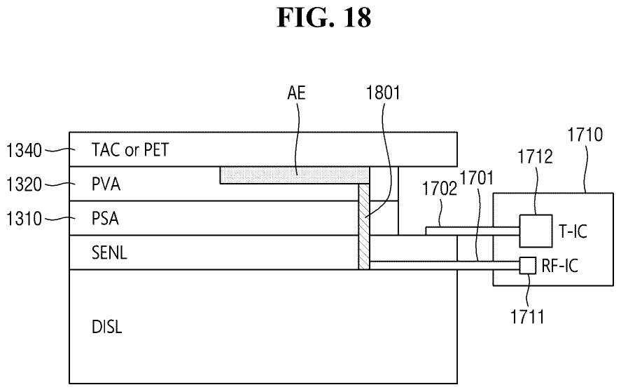

FIG. 18 is a schematic cross-sectional view illustrating a display device 10 to describe connection between an antenna electrode AE of a polarizing layer PF and an antenna circuit board 340. For example, the polarizing layer PF shown in FIG. 17 may be substantially the same as or similar to the polarizing layer PF described with reference to FIGS. 1 to 10.

the embodiment of FIG. 18 is different from the embodiment of FIG. 17 in that the antenna electrode AE of the polarizing layer PF is connected to the sensor electrode layer SENL via a through hole 1801.

Referring to FIG. 18, the polarizing layer PF, according to an embodiment of the present disclosure, may include the through hole 1801 for connecting the antenna electrode AE with the sensor electrode layer SENL.

The sensor electrode layer SENL may include an antenna wiring and an antenna pad (e.g., APD of FIG. 2), which are electrically connected to the through hole 1801.

The antenna pad APD may be disposed on one side of the sensor electrode layer SENL positioned in the non-display area NDA. An antenna FPCB 1701 may be attached to the antenna pad APD, and the antenna pad APD may be electrically connected to the circuit board 1710, in which an antenna driving circuit (e.g., RF IC) 1712 is disposed, through the antenna FPCB 1702. In this case, the circuit board 1710 may be the main circuit board 400 or the antenna circuit board 340, which is described with reference to FIGS. 1 to 5.

A touch driving circuit (e.g., touch IC) 1711 as well as the antenna driving circuit (e.g., RF IC) 1711 may be disposed in the circuit board 1710. In this case, the touch driving circuit (e.g., touch IC) 1712 may be electrically connected to touch electrodes of the sensor electrode layer SENL through a touch FPCB 1702 attached to one side of the sensor electrode layer SENL corresponding to the non-display area NDA.

In the embodiment of FIG. 18, the antenna FPCB 1702 and the touch FPCB 1701 are separately provided, but the electronic device 10 may merge these FPCBs into one FPCB. In this case, the circuit board 1710 in which the antenna driving circuit (e.g., RF IC) 1712 is disposed may be connected to the antenna pad APD through the touch FPCB 1701. Also, the touch driving circuit (e.g., touch IC) 1712 may be electrically connected to touch electrodes of the sensor electrode layer SENL through the touch FPCB 1701 attached to one side of the sensor electrode layer SENL corresponding to the non-display area NDA.

In the display device 10 and the mobile electronic device including the same according to the embodiments of the present disclosure, the polarizing film (or the polarizing layer PF) of the display panel 300 may include an antenna for communication, whereby a design space for arrangement of the components of the electronic device may be widened.

Also, the antenna electrode AE may be disposed in the polarizing film, so that interference between the display layer DISL of the display panel 300 and the antenna electrode AE may be reduced, and antenna efficiency may be enhanced.

In concluding the detailed description, those skilled in the art will appreciate that many variations and modifications can be made to the preferred embodiments without substantially departing from the principles of the present invention.

What is claimed is:

1. A display device, comprising
a display panel including a display area and a non-display area,
wherein the display panel includes:
a substrate;
a display layer disposed on the substrate;
an encapsulation layer disposed on the display layer;
a sensor electrode layer disposed on the encapsulation layer; and
a polarizing layer disposed on the sensor electrode layer, the polarizing layer including a polarizing portion corresponding to the display area and an antenna electrode corresponding to the non-display area.

2. The display device of claim 1, wherein the polarizing layer includes:
a pressure sensitive adhesive (PSA);
a polyvinyl alcohol (PVA) disposed on the PSA;
a metal layer disposed on the PVA, the metal layer including the antenna electrode; and
tri-acetyl cellulose (TAC) or polyethylene terephthalate (PET) disposed on the metal layer.

3. The display device of claim 2, wherein the antenna electrode includes:
a first antenna electrode disposed in a first non-display area, at a first side of the display area; and
a second antenna electrode disposed in a second non-display area, at a second side of the display area,
wherein the first side and the second side of the display area are adjacent to each other.

4. The display device of claim 3, wherein an elongation axis of the PVA is arranged in a first direction parallel with a short side of the display panel, and
wherein each of the first antenna electrode and the second antenna electrode has a metal mesh shape.

5. The display device of claim 3, wherein the elongation axis of the PVA is arranged in a second direction parallel with a long side of the display panel, and
wherein each of the first antenna electrode and the second antenna electrode has a metal mesh shape.

6. The display device of claim 3, wherein the elongation axis of the PVA is arranged in a diagonal direction having an angle designated with respect to a short side of the display panel, and
wherein each of the first antenna electrode and the second antenna electrode has a metal mesh shape.

7. The display device of claim 2, wherein the metal layer includes a blackening coating layer covering a surface of the antenna electrode.

8. The display device of claim 7, wherein the blackening coating layer includes a plating film including copper.

9. The display device of claim 7, wherein the blackening coating layer includes a halogenated silver salt.

10. The display device of claim 7, wherein the blackening coating layer includes a coating film including aluminum.

11. The display device of claim 7, wherein the metal layer includes an insulating film covering the blackening coating layer.

12. The display device of claim 1, wherein the polarizing layer includes:
a pressure sensitive adhesive (PSA);
a polyvinyl alcohol (PVA) disposed on the PSA;
tri-acetyl cellulose (TAC) disposed on the PVA; and
a metal layer disposed on the TAC, the metal layer including the antenna electrode.

13. The display device of claim 1, wherein the polarizing layer includes:
a pressure sensitive adhesive (PSA);
a polyvinyl alcohol (PVA) disposed on the PSA;
polyethylene terephthalate (PET) disposed on the PVA; and
a metal layer disposed on the PET, the metal layer including the antenna electrode.

14. The display device of claim 1, wherein the polarizing layer includes an antenna wiring and an antenna pad, each of which are electrically connected to the antenna electrode, and
wherein the antenna pad is connected to an antenna flexible printed circuit board (FPCB).

15. The display device of claim 1, wherein the polarizing layer includes a through hole connecting the antenna electrode with the sensor electrode layer,
wherein the sensor electrode layer includes an antenna wiring and an antenna pad, which are electrically connected to the through hole, and
wherein the antenna pad is connected to a touch flexible printed circuit board (FPCB).

16. A mobile electronic, device comprising:
a display panel including a display area and a non-display area,
wherein the display panel includes:
a substrate;
a display layer disposed on the substrate;
an encapsulation layer disposed on the display layer;
a sensor electrode layer disposed on the encapsulation layer; and
a polarizing layer disposed on the sensor electrode layer, the polarizing layer including a polarizing portion corresponding to the display area and an antenna electrode corresponding to the non-display area.

17. The mobile electronic device of claim 16, wherein the polarizing layer includes:
a pressure sensitive adhesive (PSA);
a polyvinyl alcohol (PVA) disposed on the PSA;
a metal layer disposed on the PVA, the metal layer including the antenna electrode; and
tri-acetyl cellulose (TAC) or polyethylene terephthalate (PET) disposed on the metal layer.

18. The mobile electronic device of claim 17, wherein the antenna electrode includes:
a first antenna electrode disposed in a first non-display area, at a first side of the display area; and
a second antenna electrode disposed in a second non-display area, at a second side of the display area, and
wherein the first side and the second side of the display area are adjacent to each other.

19. The mobile electronic device of claim 18, wherein an elongation axis of the PVA is arranged in a first direction parallel with a short side of the display panel, and
each of the first antenna electrode and the second antenna electrode has a metal mesh shape.

20. The mobile electronic device of claim 18, wherein an elongation axis of the PVA is arranged in a second direction parallel with a long side of the display panel, and
wherein each of the first antenna electrode and the second antenna electrode has a metal mesh shape.
